(19) United States
(12) Patent Application Publication
(10) Pub. No.: US 2009/0109762 A1
(43) Pub. Date: Apr. 30, 2009

(54) METHOD FOR PROGRAMMING NON-VOLATILE MEMORY

(75) Inventors: Chen-Hao Huang, Miaoli County (TW); Chih-Wei Hung, Hsin-chu City (TW); Chih-Yuan Chen, Yilan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: POWERCHIP SEMICONDUCTOR CORP., Hsinchu (TW)

(21) Appl. No.: 11/930,164

(22) Filed: Oct. 31, 2007

(51) Int. Cl. G11C 11/34

(52) U.S. Cl. 365/185.28

(57) ABSTRACT

A method for programming non-volatile memory utilizes substrate hot carrier effect to conduct programming operations. A forward bias voltage is applied between an N-type well region and a P-type well region so as to inject electrons in the N-type well region into the P-type well region. After that, the electrons are accelerated by a depletion region established by a voltage applied to a source region and a drain region, and a vertical electrical field established between a control gate and the P-type well region further forces the electrons to be injected into a charge storage layer. Since the present invention adopts the substrate hot carrier effect to inject carriers into the charge storage layer, the required program operation voltage is low, which benefits to save power consumption and enhance the reliability of the device.

### BACKGROUND OF THE INVENTION

1. Field of the Invention

The present invention generally relates to an operation method of non-volatile memory, and more particularly, to a method for programming NAND type non-volatile memory.

2. Description of Related Art

Among various kinds of memory products, the non-volatile memory is a kind of memory characterized by the advantages that it allows multiple data storing, reading or erasing operations. The data stored in the non-volatile memory will be retained even if the power applied to the device is cut off. The non-volatile memory has become a widely adopted memory device in personal computers and electronic equipments.

A typical non-volatile memory device usually has a stacked gate structure which includes a floating gate and a control gate both made of doped polysilicon. The floating gate is located between the control gate and a substrate. The floating gate is in floating status without wiring any circuit. The control gate is connected to word lines. In addition, the non-volatile memory device further includes a tunneling oxide layer and an inter-gate dielectric layer respectively located between the substrate and the floating gate and between the floating gate and the control gate.

In order to conduct a programming or an erasing operation on the non-volatile memory device, appropriate voltages are respectively applied to a source region, a drain region and the control gate thereof so as to inject carriers into the floating gate or to pull out carriers from the floating gate. The carrier injecting mode often used with the non-volatile memory device can be categorized into one based on channel hot carrier injection effect and the other one based on Fowler-Nordheim tunneling effect, and the like. Note that the programming and erasing operations for a non-volatile memory device are varied with the carrier injecting mode and the carrier pulling out mode.

On the other hand, a flash memory array broadly used by various users today includes NOR type array structure and NAND type array structure. Since an NAND type array non-volatile memory structure requires all memory cells in series connection to each other, therefore, the integrity and area utilization ratio thereof are better than the NOR type array non-volatile memory and more broadly used in many different electronic products.

However, for an NAND type array structure, the procedures of programming, reading and erasing memory cells thereof are more complicate. In general speaking, the operations of programming, reading and erasing memory cells in the NAND type array structure are conducted based on Fowler-Nordheim tunneling effect, wherein a high voltage is applied between the control gate and a substrate thereof so as to use the channel Fowler-Nordheim tunneling effect to force carriers from the substrate to pass through a tunneling oxide layer and then to inject the carriers into the floating gate, or to pull out the carriers from the floating gate into the substrate via the tunneling oxide layer.

Along with increasing integrity of a memory device, the tunneling oxide layer is made very thin in order to enhance the tunneling efficiency and make the device size more compact. As a result, the junction breakdown voltage of the tunneling oxide layer is accordingly reduced, which makes the tunneling oxide layer unable to withstand a high voltage required by the Fowler-Nordheim tunneling effect to fulfill the operations of programming or erasing data in the memory cells, thereby damages the tunneling oxide layer, produces leakage current and degrades the reliability of the memory.

### SUMMARY OF THE INVENTION

Accordingly, the present invention is directed to a method for programming non-volatile memory, which utilizes substrate hot carrier effect to inject carriers into a charge storage layer and is capable of saving power consumption and enhancing the reliability of a memory device due to the required lower program operation voltage.

The present invention provides a method for programming non-volatile memory suitable for an NAND type memory, wherein the memory includes a first conductive type substrate, a second conductive type well region disposed in the first conductive type substrate, a first conductive type well region disposed on the second conductive type well region, a second conductive type source region and a second conductive type drain region both disposed in the first conductive type well region, and a first select transistor, a plurality of memory cells and a second select transistor disposed in series connection to each other between the second conductive type source region and the second conductive type drain region. The first select transistor has a first select gate, each of the memory cells has a charge storage layer and a control gate, and the second select transistor has a second select gate. The programming method includes following steps. A first voltage is applied to the second conductive type well region and a second voltage is applied to the first conductive type well region so as to inject carriers from the second conductive type well region into the first conductive type well region. A third voltage is applied to the control gates of unselected memory cells and a fourth voltage is applied to the first select gate and the second select gate, wherein the third voltage is sufficient to turn on the channel region of the unselected memory cells, while the fourth voltage is sufficient to turn on the channel regions of the first select transistor and the second select transistor. A fifth voltage is applied to the control gate of selected memory cell and a sixth voltage is applied to the second conductive type source region and the second conductive type drain region, wherein the sixth voltage is for establishing a depletion region and the fifth voltage is sufficient to establish a vertical electrical field between the control gate of the select memory cell and the first conductive type well region so as to accelerate and inject the carriers into the charge storage layer of the selected memory cell by the substrate hot carrier effect.

In an embodiment of the present invention, the first conductive type is P-type; the second conductive type is N-type. The first voltage is 0 V, the second voltage is about 0.5 V to 3 V, the third voltage is about 3 V to 10 V, the fourth voltage is about 3 V to 10 V, the fifth voltage is about 13 V to 19 V and the sixth voltage is about 3 V to 10 V. The carriers include electrons.

In an embodiment of the present invention, the first conductive type is N-type; the second conductive type is P-type. The first voltage is 0 V, the second voltage is about −0.8 to −3 V, the third voltage is about −3 V to −10 V, the fourth voltage is about −3 V to −10 V, the fifth voltage is about −13 V to −19 V and the sixth voltage is about −3 V to −10 V. The carriers include holes.

In an embodiment of the present invention, the material of the charge storage layer includes doped polysilicon.

In terms of the method for programming non-volatile memory of the present invention, since a substrate hot carrier effect is adopted to inject carriers into the charge storage layer for programming operations, thus, the required program operation voltage is low, which are helpful to save power consumption, increase programming efficiency, shorten the programming time of the memory and enhance the reliability of the devices. Moreover, by using an appropriate forward bias voltage applied to the first conductive type well region and the second conductive type well region, the programming operations of the memory cells are easier to be conducted.

In addition, by adopting the substrate hot carrier injection effect and the mechanism of injecting carriers into charge storage layer, the programming operations are less affected by the channel length size of the active regions, which benefits to compact the device size, advance the electric performance and accordingly increase the device integrity.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional drawing of an NAND type non-volatile memory.

FIG. 2 is a diagram showing the method for programming an NAND type non-volatile memory with N-type channel.

FIG. 3 is a relation graph between the threshold voltage obtained by the method for programming an NAND type non-volatile memory with N-type channel of the present invention and the programming time.

FIG. 4 is a relation graph between the threshold voltage obtained by the method for programming an NAND type non-volatile memory with N-type channel of the present invention and the forward bias voltage.

FIG. 5 is a relation graph between the threshold voltage obtained by the method for programming an NAND type non-volatile memory with N-type channel of the present invention and the voltage applied to the control gate of the selected memory cell.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

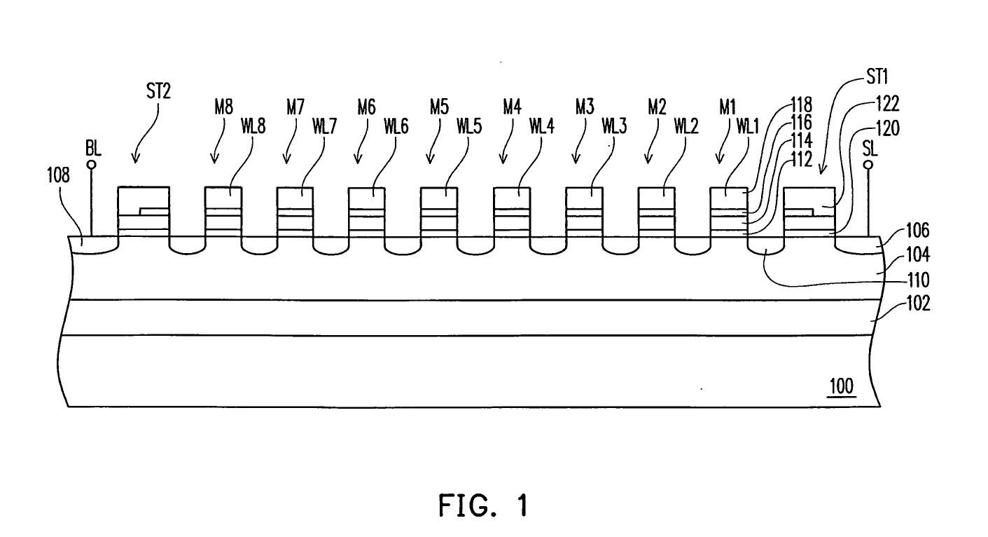

FIG. 1 is a schematic cross-sectional drawing of an NAND type non-volatile memory.

Referring to FIG. 1, an NAND type non-volatile memory includes, for example, a first conductive type substrate 100, a second conductive type well region 102, a first conductive type well region 104, a second conductive type source region 106, a second conductive type drain region 108, a first select transistor ST1, a plurality of memory cells M1-M8 and a second select transistor ST2, wherein if the first conductive type is P-type, the second conductive type is N-type; if the first conductive type is N-type, the second conductive type is P-type.

The first conductive type substrate 100 is, for example, a silicon substrate. The second conductive type well region 102 is disposed, for example, in the first conductive type substrate 100. The first conductive type well region 104 is disposed, for example, on the second conductive type well region 102.

Both the second conductive type source region 106 and second conductive type drain region 108 are disposed in the first conductive type well region 104. The first select transistor ST1, the plurality of memory cells M1-M8 and the second select transistor ST2 are disposed, for example, on the first conductive type substrate 100, while the first select transistor ST1, the memory cells M1-M8 and the second select transistor ST2 are in series connection to each other and disposed between the second conductive type source region 106 and second conductive type drain region 108.

A plurality of second conductive type doped regions 110 are respectively formed between any two adjacent memory cells M1-M8, between the memory cell M1 and the first select transistor ST1 and between the memory cell M8 and the second select transistor ST2, and all of second conductive type doped regions 110 are located in the first conductive type substrate 100, so that the first select transistor ST1, the plurality of memory cells M1-M8 and the second select transistor ST2 are in series connection to each other through the nine second conductive type doped region 110 to form a memory cell row. In addition, the second conductive type source region 106 is connected to a source line SL and the second conductive type drain region 108 is connected to a bit line BL.

Each of the memory cells M1-M8 includes a tunneling dielectric layer 112, a charge storage layer 114, an inter-gate dielectric layer 116 and a control gate 118. The control gate 118, the inter-gate dielectric layer 116, the charge storage layer 114 and the tunneling dielectric layer 112 are, for example, sequentially stacked from the first conductive type substrate 100 up.

The control gate 118 is disposed, for example, on the first conductive type substrate 100 and is made of, for example, conductive material such as doped polysilicon, metal or silicide. The control gate 118 of each of the memory cells M1-M8 are respectively connected to a corresponding word line (WL1-WL8).

The charge storage layer 114 is disposed, for example, between the control gate 118 and the first conductive type substrate 100. The material of the charge storage layer 114 includes conductive material (for example, doped polysilicon) or charge trapping material (for example, silicon nitride).

The tunneling dielectric layer 112 is disposed, for example, between the first conductive type substrate 100 and the charge storage layer 114. The material of the tunneling dielectric layer 112 is, for example, silicon oxide. The inter-gate dielectric layer 116 is disposed, for example, between the control gate 118 and the charge storage layer 114. The material of the inter-gate dielectric layer 116 is, for example, silicon oxide, silicon nitride, silicon nitride oxide, high K dielectric materials (for example, Ta₂O₅, Al₂O₃, HfO₂, HfON, HfAlO, HfAlON) or composite dielectric material, for example, silicon oxide/silicon nitride, silicon oxide/silicon nitride/silicon oxide , silicon oxide/high K, silicon oxide/high K/silicon oxide. The high K dielectric materials have a dielectric constant not less than 4.

Each of the first select transistor ST1 and the second select transistor ST2 includes a gate dielectric layer 120 and a select gate 122, wherein the gate dielectric layer 120 is disposed between the select gate 122 and the first conductive type substrate 100. The gate dielectric layer 120 is made of, for example, silicon oxide. The material of the select gate 122 is conductive materials, for example, doped polysilicon, metal or silicide.

The above-mentioned NAND type non-volatile memory can be programmed by using substrate hot carrier effect. In the embodiment, an NAND type non-volatile memory with N-type channel is exemplarily described. That is, the first conductive type substrate 100 in FIG. 1 is, for example, a P-type substrate, the second conductive type well region 102 is an N-type well region, the first conductive type well region 104 is a P-type well region, and all the source region 106 and the drain region 108 are N-type doped regions.

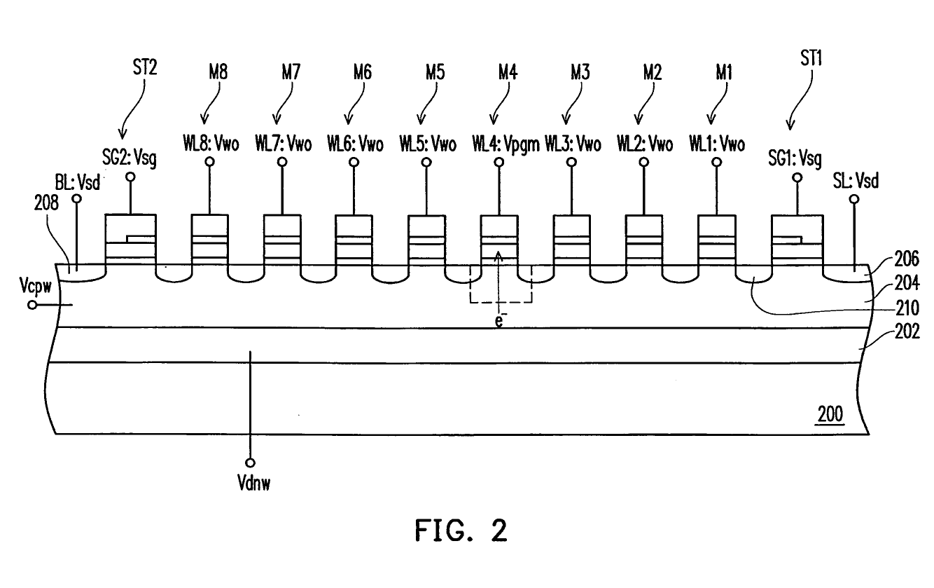

FIG. 2 is a diagram showing the method for programming an NAND type non-volatile memory with N-type channel.

Referring to FIG. 2, as a programming operation is conducted on a selected memory cell, for example, M4, a voltage Vdnw and a voltage Vcpw are respectively applied to an N-type well region 202 and a P-type well region 204. A voltage Vwo is respectively applied to the control gates of the unselected memory cells M1-M3 and M5-M8 (word lines WL1-WL3 and WL5-WL8), and a voltage Vsg is respectively applied to a first select gate SG1 and a second select gate SG2. In addition, a voltage Vpgm is applied to the control gate (word line WL4) of the selected memory cell M4, and a voltage Vsd is respectively applied to a source region 206 (source line SL) and a drain region 208 (bit line BL). With the above-mentioned applied voltages, the substrate hot carrier effect is activated so as to enable the electrons in the N-type well region 202 to be injected into the P-type well region 204, following by being accelerated by a depletion region and a vertical electrical field to be finally injected into the charge storage layer of the selected memory cell M4.

The voltage Vdnw and the voltage Vcpw forms a forward bias voltage between the N-type well 202 and the P-type well 204, which enables the electrons of the N-type well 202 to be injected into the P-type well 204. The voltage Vwo is sufficient to turn on the channel regions of the unselected memory cells M1-M3 and M5-M8. The voltage Vsg is sufficient to turn on the channel regions of the first select gate SG1 and the second select gate SG2. During programming the memory cell M4, the unselected memory cells M1-M3 and M5-M8, the first select gate SG1 and the second select gate SG2 are served as transmission transistors so as to make the doped regions located at both sides of the selected memory cell M4, the source region 206 (source line SL) and the drain region 208 (bit line BL) have an equal level. The voltage Vsd applied to the source region 206 and the drain region 208 establishes a depletion region for the electrons in the P-type well 204 to be further accelerated. The voltage Vpgm is sufficient to establish a vertical electrical field between the control gate of the memory cell M4 and the P-type well 204. Thus, electrons are injected into the P-type well 204 from the N-type well 202, then, accelerated by the depletion region formed by the voltage applied to the source region 206 (source line SL) and the drain region 208 (bit line BL). Thereafter, the vertical electrical field established between the control gate and the P-type well 204 makes the electrons injected into the charge storage layer of the selected memory cell M4. In this way, the selected memory cell M4 is programmed by using the substrate hot carrier effect.

The voltage Vdnw herein is 0 V, the voltage Vcpw is about 0.5 V to 3 V, the voltage Vwo is about 3 V to 10 V, the voltage Vsg is about 3 V to 10 V, the voltage Vpgm is about 13 V to 19 V and the voltage Vsd is about 3 V to 10 V.

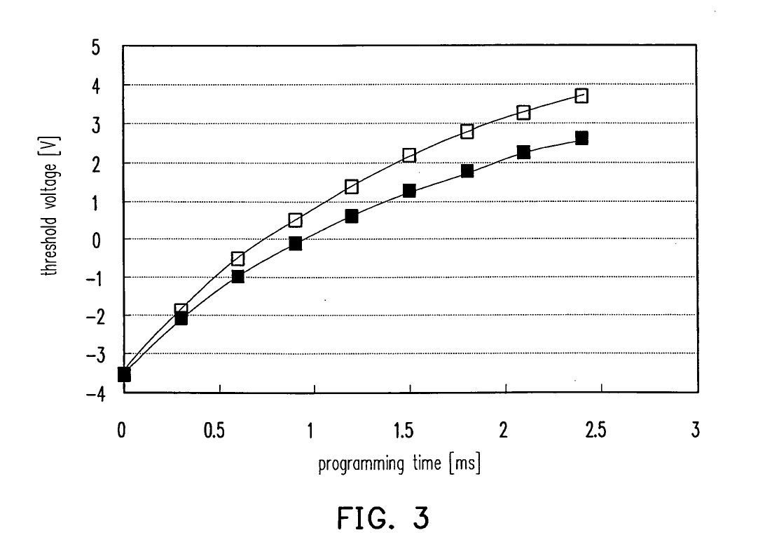

FIG. 3 is a relation graph between the threshold voltage obtained by the method for programming an NAND type non-volatile memory with N-type channel of the present invention and the programming time. In FIG. 3, an experiment 1 (notated by symbol ▪) is corresponding to that a 0 V voltage is applied to the N-type well 202, a 1 V voltage is applied to the P-type well 204, a 5 V voltage is respectively applied to the control gates (word lines WL1-WL3 and WL5-WL8) of the memory cells M1-M3 and M5-M8, a 5 V voltage is respectively applied to the first select transistor ST1 and the second select transistor ST2, a 5 V voltage is respectively applied to the source region 206 (the source line SL) and the drain region 208 (the bit line BL) and a 15 V voltage is applied to the control gate (the word line WL4) of the selected memory cell M4. Another experiment 2 (notated by symbol c) has the same conditions as the experiment 1 except a 17 V voltage, instead of 15 V, is applied to the control gate (the word line WL4) of the selected memory cell M4.

As shown by FIG. 3, in terms both of the experiments 1 and 2, the threshold voltages of the selected memory cell M4 are increased with the increasing programming time, wherein a threshold voltage indicates electrons are able to enter the charge storage layer of the memory cell M4. In particular, the higher the voltage applied to the control gate (the word line WL4) of the selected memory cell M4, the threshold voltage of the selected memory cell M4 increases the faster.

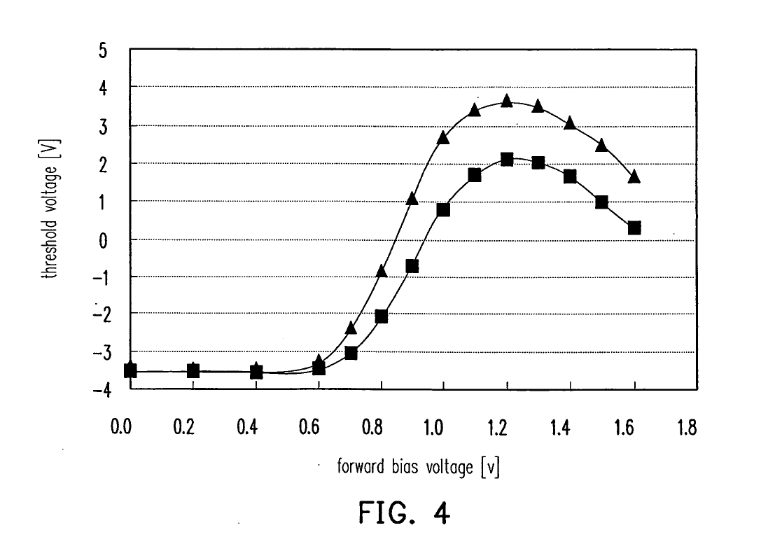

FIG. 4 is a relation graph between the threshold voltage obtained by the method for programming an NAND type non-volatile memory with N-type channel of the present invention and the forward bias voltage, wherein the forward bias voltage means the voltage difference between the P-type well 204 and the N-type well 202. In FIG. 4, an experiment 3 (notated by symbol ▪) is corresponding to the case where almost all conditions are the same as the experiment 1 except the voltage applied to the P-type well 204 is about 0 V to 1.6 V. The programming time for the experiment 3 is 1.2 ms. An experiment 4 in FIG. 4 (notated by symbol ▴) has the same conditions as the experiment 3 except the programming time for the experiment 3 is 2.4 ms rather than 1.2 ms.

As shown by FIG. 4, in terms both of the experiments 3 and 4, along with a continuingly increasing forward bias voltage, the threshold voltage of the selected memory cell M4 is increased first, and then decreased. When a forward bias voltage is not high enough (0 V to 0.6 V), the electrons of the N-type well 202 fail to be injected into the P-type well 204 and thereby the memory cell M4 is not able to be programmed which makes the threshold voltage almost unchanged. When a forward bias voltage is high enough (1.0 V to 1.6 V), the electrons of the N-type well 202 are able to be injected into the P-type well 204, following by being accelerated to enter the charge storage layer of the memory cell M4 to finish the job of programming the memory cell M4, which makes the threshold voltage of the memory cell M4 increased. When a forward bias voltage is extreme high (1.2 V to 1.6 V), the voltage difference between the P-type well 204 and the control gate of the memory cell M4 gets smaller, so that the depletion region shrinks and the electrical field intensity gets weaker and the expected high energy electrons get less, and the threshold voltage is accordingly decreased. In the experiments, the voltage difference between the P-type well 204 and the N-type well 202 is, for example, 0.8 V to 1.6 V and preferably 1.0 V to 1.4 V.

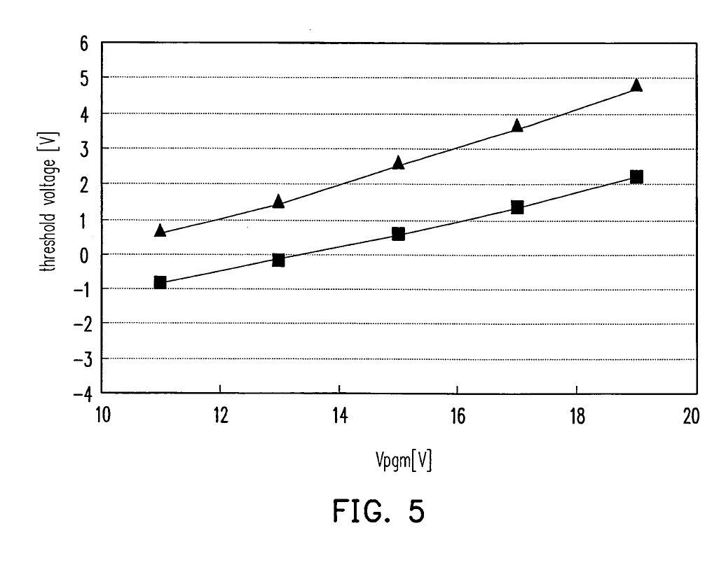

FIG. 5 is a relation graph between the threshold voltage obtained by the method for programming an NAND type non-volatile memory with N-type channel of the present invention and the voltage applied to the control gate of the selected memory cell. In FIG. 5, an experiment 5 (notated by symbol ▪) is corresponding to the case where almost all conditions are the same as the experiment 1 except the voltage applied to the control gate of the selected memory cell is about 11 V to 19 V. The programming time for the experiment 5 is 1.2 ms. An experiment 6 in FIG. 5 (notated by symbol ▴) has the same conditions as the experiment 5 except the programming time for the experiment 6 is 2.4 ms rather than 1.2 ms.

As shown by FIG. 5, in terms both of the experiments 5 and 6, along with a continuingly increasing forward bias voltage applied to the control gate of the selected memory cell, the threshold voltage of the selected memory cell M4 is increased as well. The higher the voltage applied to the control gate of the selected memory cell, the programming speed gets the faster. According to the experiment results of FIGS. 3-5, it can be proved the method of the present invention is able to effectively program the NAND type non-volatile memory with N-type channel. In comparison the programming method of the present invention with the conventional method based on Fowler-Nordheim tunneling effect, it is clear the operation voltage required by the present invention is lower which contributes to save power consumption.

The hereinabove embodiment is exemplarily regarding, but not limited by the present invention, an NAND type non-volatile memory with N-type channel. The present invention certainly covers an NAND type non-volatile memory with P-type channel as well, referring to FIG. 1.

In FIG. 1, the first conductive type substrate 100 is, for example, an N-type substrate, while the second conductive type well region 102 is a P-type well region, the first conductive type well region 104 is an N-type well region, and the second conductive type source region 106, the second conductive type drain region 108 and the second conductive type doped region 110 are P-type doped regions. In addition, the operation voltage of an NAND type non-volatile memory with P-type channel is opposite to the operation voltage of an NAND type non-volatile memory with N-type channel; the carriers injected into the charge storage layer in an NAND type non-volatile memory with N-type channel are electrons, while the carriers in an NAND type non-volatile memory with P-type channel are holes.

Table 1 gives out the statuses of the required bias voltages applied to different electrodes for programming an NAND type non-volatile memory with N-type channel and an NAND type non-volatile memory with P-type channel.

TABLE 1

| | With N-type | With P-type |
|---|---|---|
| Different Electrodes | Channel | Channel |
| well region (102) | 0 V | 0 V |
| well region (104) | positive voltage | negative voltage |
| unselected memory cell | positive voltage | negative voltage |
| (word line) | | |
| selected transistor ST1, ST2 | positive voltage | negative voltage |
| drain region (106) | positive voltage | negative voltage |
| drain region (108) | | |
| selected memory cell | positive voltage | negative voltage |

In summary, since the method for programming non-volatile memory provided by the present invention adopts substrate hot carrier effect to inject carriers into the charge storage layer to conduct programming operations, therefore, the required program operation voltage is low , which are helpful to save power consumption, increase programming efficiency, shorten the programming time of the memory and enhance the reliability of the devices. Moreover, by using an appropriate forward bias voltage applied to the first conductive type well region and the second conductive type well region, the programming operations of the memory cells are easier to be conducted.

In addition, by adopting the substrate hot carrier injection effect and the mechanism of injecting carriers into charge storage layer, the programming operations are less affected by the channel length size of the active regions, which benefits to compact the device size, advance the electric performance and accordingly increase the device integrity

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for programming non-volatile memory, wherein the non-volatile memory comprises a first conductive type substrate, a second conductive type well region disposed in the first conductive type substrate, a first conductive type well region disposed on the second conductive type well region, a second conductive type source region and a second conductive type drain region disposed in the first conductive type well region, and a first select transistor, a plurality of memory cells and a second select transistor disposed in series connection to each other between the second conductive type source region and the second conductive type drain region, wherein the first select transistor has a first select gate, each of the memory cells has a charge storage layer and a control gate, and the second select transistor has a second select gate; the programming method comprising:
applying a first voltage to the second conductive type well region and applying a second voltage to the first conductive type well region so as to inject carriers from the second conductive type well region into the first conductive type well region;
applying a third voltage to the control gates of unselected memory cells and applying a fourth voltage to the first select gate and the second select gate, wherein the third voltage is sufficient to turn on channel regions of the unselected memory cells, while the fourth voltage is sufficient to turn on channel regions of the first select transistor and the second select transistor; and
applying a fifth voltage to the control gate of a selected memory cell and applying a sixth voltage to the second conductive type source region and the second conductive type drain region, wherein the sixth voltage is for establishing a depletion region and the fifth voltage is sufficient to establish a vertical electrical field between the control gate of the selected memory cell and the first conductive type well region so as to accelerate and inject carriers into the charge storage layer of the selected memory cell by the substrate hot carrier effect.

2. The method for programming non-volatile memory according to claim 1, wherein the first conductive type is P-type and the second conductive type is N-type.

3. The method for programming non-volatile memory according to claim 2, wherein the first voltage is 0 V and the second voltage is about 0.5 V to 3 V.

4. The method for programming non-volatile memory according to claim 2, wherein the third voltage is about 3 V to 10 V and the fourth voltage is about 3 V to 10 V.

5. The method for programming non-volatile memory according to claim 2, wherein the fifth voltage is about 13 V to 19 V and the sixth voltage is about 3 V to 10 V.

6. The method for programming non-volatile memory according to claim 2, wherein the carriers comprise electrons.

7. The method for programming non-volatile memory according to claim 1, wherein the first conductive type is N-type and the second conductive type is P-type.

8. The method for programming non-volatile memory according to claim 7, wherein the first voltage is 0 V and the second voltage is about −0.5 V to −3 V.

9. The method for programming non-volatile memory according to claim 7, wherein the third voltage is about −3 V to −10 V and the fourth voltage is about −3 V to −10 V.

10. The method for programming non-volatile memory according to claim 7, wherein the fifth voltage is about −13 V to −19 V and the sixth voltage is about −3 V to −10 V.

11. The method for programming non-volatile memory according to claim 4, wherein the carriers comprise holes.

12. The method for programming non-volatile memory according to claim 1, wherein the material of the charge storage layer comprises doped polysilicon.
